(19) United States
(12) Patent Application Publication
(10) Pub. No.: US 2025/0349567 A1
(43) Pub. Date: Nov. 13, 2025

(54) HEAT TREATMENT APPARATUS FOR HEATING SUBSTRATE BY LIGHT IRRADIATION

(71) Applicant: SCREEN Holdings Co., Ltd., Kyoto (JP)

(72) Inventor: Shogo SHIGEMASU, Kyoto-shi (JP)

(21) Appl. No.: 19/098,981

(22) Filed: Apr. 3, 2025

(30) Foreign Application Priority Data
May 8, 2024 (JP) 2024-075895

(51) Int. Cl. H01L 21/67

(52) U.S. Cl. CPC H01L 21/67115

(57) ABSTRACT

An anti-reflective film is formed on upper and lower surfaces of an upper chamber window which is one quartz part provided between a semiconductor wafer held in a chamber by a holder and flash lamps provided over the chamber. The anti-reflective film is composed of a multi-layer combination of multiple types of dielectric films. The anti-reflective film reduces the reflectance of light in a wavelength range including at least a target wavelength when the target wavelength is a wavelength component such that an intensity relative to a maximum peak which has the highest intensity is not less than 0.1 in a spectrum of the flash lamps. The formation of the anti-reflective film on the upper chamber window made of quartz reduces the reflectance of flashes of light at the upper and lower surfaces of the upper chamber window to suppress the reflection of light at the interfaces.

### BACKGROUND

### Technical Field

The present invention relates to a heat treatment apparatus which irradiates a substrate with light to heat the substrate. Examples of the substrate to be treated include a semiconductor wafer, a substrate for a liquid crystal display device, a substrate for a flat panel display (FPD), a substrate for an optical disk, a substrate for a magnetic disk, and a substrate for a solar cell.

### Description of the Background Art

In the process of manufacturing a semiconductor device, attention has been given to flash lamp annealing (FLA) which heats a semiconductor wafer in an extremely short time. The flash lamp annealing is a heat treatment technique in which xenon flash lamps (the term “flash lamp” as used hereinafter refers to a “xenon flash lamp”) are used to irradiate a surface of a semiconductor wafer with a flash of light, thereby raising the temperature of only the surface of the semiconductor wafer in an extremely short time (several milliseconds or less).

The xenon flash lamps have a spectral distribution of radiation ranging from ultraviolet to near-infrared regions. The wavelength of light emitted from the xenon flash lamps is shorter than that of light emitted from conventional halogen lamps, and approximately coincides with a fundamental absorption band of a silicon semiconductor wafer. Thus, when a semiconductor wafer is irradiated with a flash of light emitted from the xenon flash lamps, the temperature of the semiconductor wafer can be raised rapidly, with only a small amount of light transmitted through the semiconductor wafer. Also, it has turned out that flash irradiation, that is, the irradiation of a semiconductor wafer with a flash of light in an extremely short time of several milliseconds or less allows a selective temperature rise only near the surface of the semiconductor wafer.

Such flash lamp annealing is used for processes that require heating with a low thermal history (providing a small amount of heat), e.g. typically for the activation of impurities implanted in a semiconductor wafer. The irradiation of the surface of the semiconductor wafer implanted with impurities by an ion implantation process with a flash of light emitted from the flash lamps allows the temperature rise in the surface of the semiconductor wafer to an activation temperature only for an extremely short time to result in a low thermal history, thereby achieving only the activation of the impurities without deep diffusion of the impurities. In general, it is difficult for flash irradiation alone to cause the surface temperature of the semiconductor wafer to reach a target temperature. For this reason, the surface of the semiconductor wafer preheated to a predetermined temperature by halogen lamps and the like is irradiated with a flash of light (as disclosed, for example, in Japanese Patent Application Laid-Open No. 2018-101760).

The flash lamp annealing for an extremely short irradiation time period can suppress the deep diffusion of impurities. In recent years, however, there has been a demand for heating methods with an even lower thermal history in order to suppress diffusion on the order of angstroms. To achieve an even lower thermal history in the flash lamp annealing, it is necessary to make the preheating temperature as low as possible and to increase a jump temperature from the preheating temperature to a target temperature during flash irradiation.

Unfortunately, flashes of light are reflected at an interface of a quart window of a chamber which is present between the flash lamps and a semiconductor wafer during the flash irradiation. As a result, the amount of light impinging upon the semiconductor wafer is reduced. This is one of the factors that prevent the achievement of a high jump temperature.

In addition, there arises another problem such that the uniformity of an in-plane temperature distribution of the semiconductor wafer is impaired because cold spots of the semiconductor wafer (e.g., a peripheral portion of the semiconductor wafer where heat dissipation is liable to occur) are not irradiated with a sufficient amount of light during the flash irradiation.

To achieve a reduction in environmental loads in the flash lamp annealer, it is necessary that the target temperature of the semiconductor wafer is reached with low power consumption. However, the light reflection occurs at the quartz window of the chamber to cause a certain amount of light to be lost as mentioned above, resulting in unnecessary power consumption. As a result, the heating treatment with low power consumption has been also inhibited.

### SUMMARY

The present invention is intended for a heat treatment apparatus for irradiating a substrate with light to heat the substrate.

According to one aspect of the present invention, the heat treatment apparatus comprises: a chamber for receiving a substrate therein; a holder for holding the substrate in the chamber; and a heating light source provided outside the chamber and for irradiating the substrate held by the holder with light, wherein an anti-reflective film is formed on a quartz part provided between the heating light source and the substrate held by the holder.

This reduces the reflectance of light at an interface of the quartz part to suppress the reflection of light at the interface of the quartz part.

Preferably, the anti-reflective film is formed on both surfaces of the quartz part.

This further improves the reflection suppression effect of the whole quartz part.

Preferably, the quartz part is the quartz window, and the anti-reflective film is formed on an outer surface opposite an inner surface of the quartz window which is in contact with a heat treatment space in the chamber.

This prevents contamination in the chamber resulting from the anti-reflective film.

Preferably, the quartz part is the quartz window, and the anti-reflective film is formed on a location opposed to a region where temperature is relatively low in a temperature distribution occurring in the substrate when the substrate held by the holder is irradiated with light.

This increases the amount of light impinging upon the region where temperature is relatively low to improve the uniformity of an in-plane temperature distribution of the substrate.

It is therefore an object of the present invention to suppress the reflection of light at an interface of a quartz part.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a longitudinal sectional view showing a configuration of a heat treatment apparatus according to the present invention;

FIG. 2 is a perspective view showing the entire external appearance of a holder;

FIG. 3 is a plan view of a susceptor;

FIG. 4 is a sectional view of the susceptor;

FIG. 5 is a plan view of a transfer mechanism;

FIG. 6 is a side view of the transfer mechanism;

FIG. 7 is a plan view showing an arrangement of halogen lamps;

FIG. 8 is a partial sectional view of an upper chamber window with an anti-reflective film formed thereon;

FIG. 9 is a graph showing part of an emission spectrum of xenon flash lamps;

FIG. 10 is a schematic view for illustrating the principle of reflectance reduction using the anti-reflective film;

FIG. 11 is a view showing another example of the formation of the anti-reflective film; and

FIG. 12 is a graph showing an emission spectrum of a vertical cavity surface emitting laser.

### DESCRIPTION OF THE PREFERRED EMBODIMENTS

A preferred embodiment according to the present invention will now be described in detail with reference to the drawings. In the following description, expressions indicating relative or absolute positional relationships (e.g., “in one direction”, “along one direction”, “parallel”, “orthogonal”, “center”, “concentric”, and “coaxial”) shall represent not only the exact positional relationships but also a state in which the angle or distance is relatively displaced to the extent that tolerances or similar functions are obtained, unless otherwise specified. Also, expressions indicating equal states (e.g., “identical”, “equal”, and “homogeneous”) shall represent not only a state of quantitative exact equality but also a state in which there are differences that provide tolerances or similar functions, unless otherwise specified. Also, expressions indicating shapes (e.g., “circular”, “rectangular”, and “cylindrical”) shall represent not only the geometrically exact shapes but also shapes to the extent that the same level of effectiveness is obtained, unless otherwise specified, and may have unevenness or chamfers. Also, an expression such as “comprising”, “equipped with”, “provided with”, “including”, or “having” a component is not an exclusive expression that excludes the presence of other components. Also, the expression “at least one of A, B, and C” includes “A only”, “B only”, “C only”, “any two of A, B, and C”, and “all of A, B, and C”.

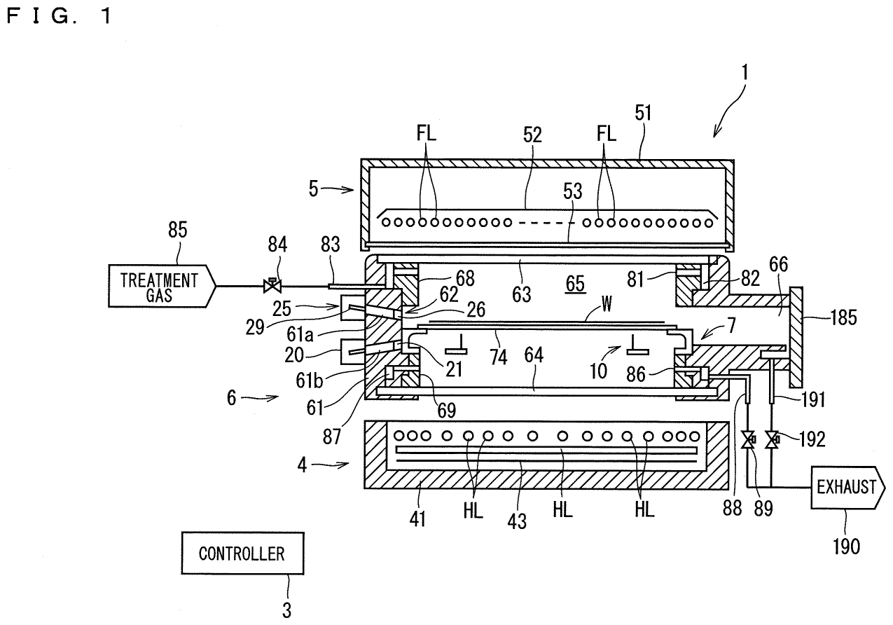

FIG. 1 is a longitudinal sectional view showing a configuration of a heat treatment apparatus 1 according to the present invention. The heat treatment apparatus 1 of FIG. 1 is a flash lamp annealer for irradiating a disk-shaped semiconductor wafer W serving as a substrate with flashes of light to heat the semiconductor wafer W. The size of the semiconductor wafer W to be treated is not particularly limited. For example, the semiconductor wafer W to be treated has a diameter of 300 mm and 450 mm (in the present preferred embodiment, 300 mm). It should be noted that the dimensions of components and the number of components are shown in exaggeration or in simplified form, as appropriate, in FIG. 1 and the subsequent figures for the sake of easier understanding.

The heat treatment apparatus 1 includes a chamber 6 for receiving a semiconductor wafer W therein, a flash heating part 5 including a plurality of built-in flash lamps FL, and a halogen heating part 4 including a plurality of built-in halogen lamps HL. The flash heating part 5 is provided over the chamber 6, and the halogen heating part 4 is provided under the chamber 6. The heat treatment apparatus 1 further includes a holder 7 provided inside the chamber 6 and for holding a semiconductor wafer W in a horizontal attitude, and a transfer mechanism 10 provided inside the chamber 6 and for transferring a semiconductor wafer W between the holder 7 and the outside of the heat treatment apparatus 1. The heat treatment apparatus 1 further includes a controller 3 for controlling operating mechanisms provided in the halogen heating part 4, the flash heating part 5, and the chamber 6 to cause the operating mechanisms to heat-treat a semiconductor wafer W.

The chamber 6 is configured such that upper and lower chamber windows 63 and 64 made of quartz are mounted to the top and bottom, respectively, of a tubular chamber side portion 61. The chamber side portion 61 has a generally tubular shape having an open top and an open bottom. The upper chamber window 63 is mounted to block the top opening of the chamber side portion 61, and the lower chamber window 64 is mounted to block the bottom opening thereof. The upper chamber window 63 forming the ceiling of the chamber 6 is a disk-shaped member made of quartz, and serves as a quartz window that transmits flashes of light emitted from the flash heating part 5 therethrough into the chamber 6. The lower chamber window 64 forming the floor of the chamber 6 is also a disk-shaped member made of quartz, and serves as a quartz window that transmits light emitted from the halogen heating part 4 therethrough into the chamber 6. The upper chamber window 63 which is a quartz window covering the top opening of the chamber 6 has a dielectric film deposited thereon as an anti-reflective film, which will be described further later.

An upper reflective ring 68 is mounted to an upper portion of the inner wall surface of the chamber side portion 61, and a lower reflective ring 69 is mounted to a lower portion thereof. Both of the upper and lower reflective rings 68 and 69 are in the form of an annular ring. The upper reflective ring 68 is mounted by being inserted downwardly from the top of the chamber side portion 61. The lower reflective ring 69, on the other hand, is mounted by being inserted upwardly from the bottom of the chamber side portion 61 and fastened with screws not shown. In other words, the upper and lower reflective rings 68 and 69 are removably mounted to the chamber side portion 61. An interior space of the chamber 6, i.e. a space surrounded by the upper chamber window 63, the lower chamber window 64, the chamber side portion 61, and the upper and lower reflective rings 68 and 69, is defined as a heat treatment space 65.

A recessed portion 62 is defined in the inner wall surface of the chamber 6 by mounting the upper and lower reflective rings 68 and 69 to the chamber side portion 61. Specifically, the recessed portion 62 is defined which is surrounded by a middle portion of the inner wall surface of the chamber side portion 61 where the reflective rings 68 and 69 are not mounted, a lower end surface of the upper reflective ring 68, and an upper end surface of the lower reflective ring 69. The recessed portion 62 is provided in the form of a horizontal annular ring in the inner wall surface of the chamber 6, and surrounds the holder 7 which holds a semiconductor wafer W. The chamber side portion 61 and the upper and lower reflective rings 68 and 69 are made of a metal material (e.g., stainless steel) with high strength and high heat resistance.

The chamber side portion 61 is provided with a transport opening (throat) 66 for the transport of a semiconductor wafer W therethrough into and out of the chamber 6. The transport opening 66 is openable and closable by a gate valve 185. The transport opening 66 is connected in communication with an outer peripheral surface of the recessed portion 62. Thus, when the transport opening 66 is opened by the gate valve 185, a semiconductor wafer W is allowed to be transported through the transport opening 66 and the recessed portion 62 into and out of the heat treatment space 65. When the transport opening 66 is closed by the gate valve 185, the heat treatment space 65 in the chamber 6 is an enclosed space.

The chamber side portion 61 is further provided with a through hole 61a and a through hole 61b both bored therein. The through hole 61a is a cylindrical hole for directing infrared light emitted from an upper surface of a semiconductor wafer W held by a susceptor 74 to be described later therethrough to an infrared sensor 29 of an upper radiation thermometer 25. The through hole 61b is a cylindrical hole for directing infrared light emitted from a lower surface of the semiconductor wafer W therethrough to a lower radiation thermometer 20. The through holes 61a and 61b are inclined with respect to a horizontal direction so that the longitudinal axes (axes extending in respective directions in which the through holes 61a and 61b extend through the chamber side portion 61) of the respective through holes 61a and 61b intersect main surfaces of the semiconductor wafer W held by the susceptor 74. A transparent window 26 made of calcium fluoride material transparent to infrared light in a wavelength range measurable with the upper radiation thermometer 25 is mounted to an end portion of the through hole 61a which faces the heat treatment space 65. A transparent window 21 made of barium fluoride material transparent to infrared light in a wavelength range measurable with the lower radiation thermometer 20 is mounted to an end portion of the through hole 61b which faces the heat treatment space 65.

At least one gas supply opening 81 for supplying a treatment gas therethrough into the heat treatment space 65 is provided in an upper portion of the inner wall of the chamber 6. The gas supply opening 81 is provided above the recessed portion 62, and may be provided in the upper reflective ring 68. The gas supply opening 81 is connected in communication with a gas supply pipe 83 through a buffer space 82 provided in the form of an annular ring inside the side wall of the chamber 6. The gas supply pipe 83 is connected to a treatment gas supply source 85. A valve 84 is interposed in the gas supply pipe 83. When the valve 84 is opened, the treatment gas is fed from the treatment gas supply source 85 to the buffer space 82. The treatment gas flowing in the buffer space 82 flows in a spreading manner within the buffer space 82 which is lower in fluid resistance than the gas supply opening 81, and is supplied through the gas supply opening 81 into the heat treatment space 65. Examples of the treatment gas usable herein include inert gases such as nitrogen gas (N₂), reactive gases such as hydrogen (H₂) and ammonia (NH₃), and mixtures of these gases (although nitrogen gas is used in the present preferred embodiment).

At least one gas exhaust opening 86 for exhausting a gas from the heat treatment space 65 is provided in a lower portion of the inner wall of the chamber 6. The gas exhaust opening 86 is provided below the recessed portion 62, and may be provided in the lower reflective ring 69. The gas exhaust opening 86 is connected in communication with a gas exhaust pipe 88 through a buffer space 87 provided in the form of an annular ring inside the side wall of the chamber 6. The gas exhaust pipe 88 is connected to an exhaust part 190. A valve 89 is interposed in the gas exhaust pipe 88. When the valve 89 is opened, the gas in the heat treatment space 65 is exhausted through the gas exhaust opening 86 and the buffer space 87 to the gas exhaust pipe 88. The at least one gas supply opening 81 and the at least one gas exhaust opening 86 may include a plurality of gas supply openings 81 and a plurality of gas exhaust openings 86, respectively, arranged in a circumferential direction of the chamber 6, and may be in the form of slits. The treatment gas supply source 85 and the exhaust part 190 may be mechanisms provided in the heat treatment apparatus 1 or be utility systems in a factory in which the heat treatment apparatus 1 is installed.

A gas exhaust pipe 191 for exhausting the gas from the heat treatment space 65 is also connected to a distal end of the transport opening 66. The gas exhaust pipe 191 is connected through a valve 192 to the exhaust part 190. By opening the valve 192, the gas in the chamber 6 is exhausted through the transport opening 66.

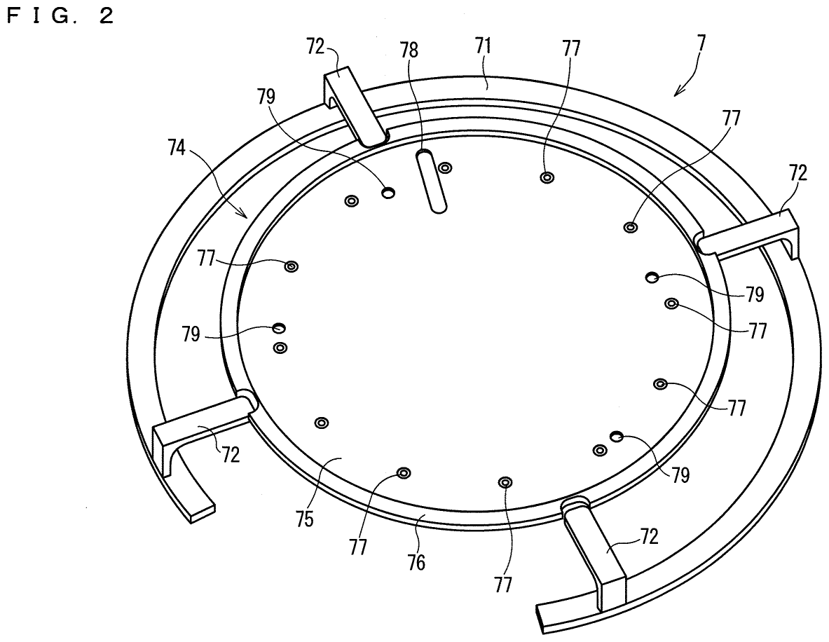

FIG. 2 is a perspective view showing the entire external appearance of the holder 7. The holder 7 includes a base ring 71, coupling portions 72, and the susceptor 74. The base ring 71, the coupling portions 72, and the susceptor 74 are all made of quartz. In other words, the whole of the holder 7 is made of quartz.

The base ring 71 is a quartz member having an arcuate shape obtained by removing a portion from an annular shape. This removed portion is provided to prevent interference between transfer arms 11 of the transfer mechanism 10 to be described later and the base ring 71. The base ring 71 is supported by the wall surface of the chamber 6 by being placed on the bottom surface of the recessed portion 62 (with reference to FIG. 1). The multiple coupling portions 72 (in the present preferred embodiment, four coupling portions 72) are mounted upright on the upper surface of the base ring 71 and arranged in a circumferential direction of the annular shape thereof. The coupling portions 72 are quartz members, and are rigidly secured to the base ring 71 by welding.

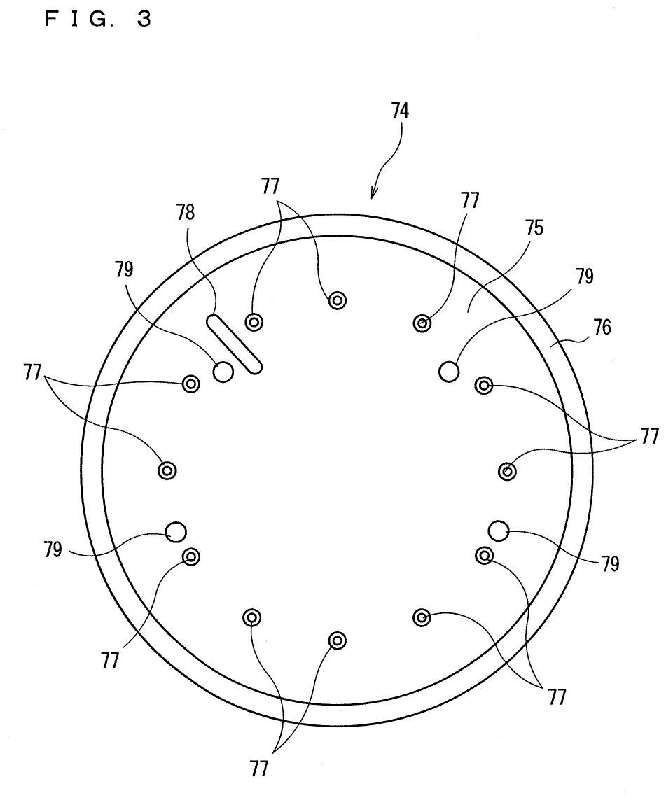

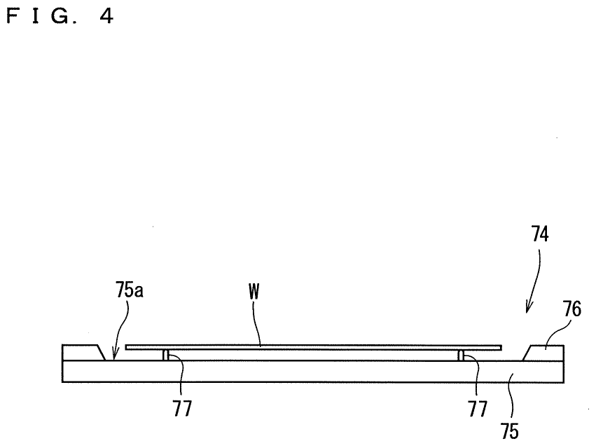

The susceptor 74 is supported by the four coupling portions 72 provided on the base ring 71. FIG. 3 is a plan view of the susceptor 74. FIG. 4 is a sectional view of the susceptor 74. The susceptor 74 includes a holding plate 75, a guide ring 76, and a plurality of substrate support pins 77. The holding plate 75 is a generally circular planar member made of quartz. The diameter of the holding plate 75 is greater than that of a semiconductor wafer W. In other words, the holding plate 75 has a size, as seen in plan view, greater than that of the semiconductor wafer W.

The guide ring 76 is provided on a peripheral portion of the upper surface of the holding plate 75. The guide ring 76 is an annular member having an inner diameter greater than the diameter of the semiconductor wafer W. For example, when the diameter of the semiconductor wafer W is 300 mm, the inner diameter of the guide ring 76 is 320 mm. The inner periphery of the guide ring 76 is in the form of a tapered surface which becomes wider in an upward direction from the holding plate 75. The guide ring 76 is made of quartz similar to that of the holding plate 75. The guide ring 76 may be welded to the upper surface of the holding plate 75 or fixed to the holding plate 75 with separately machined pins and the like. Alternatively, the holding plate 75 and the guide ring 76 may be machined as an integral member.

A region of the upper surface of the holding plate 75 which is inside the guide ring 76 serves as a planar holding surface 75a for holding the semiconductor wafer W. The substrate support pins 77 are provided upright on the holding surface 75a of the holding plate 75. In the present preferred embodiment, a total of 12 substrate support pins 77 are spaced at intervals of 30 degrees along the circumference of a circle concentric with the outer circumference of the holding surface 75a (the inner circumference of the guide ring 76). The diameter of the circle on which the 12 substrate support pins 77 are disposed (the distance between opposed ones of the substrate support pins 77) is smaller than the diameter of the semiconductor wafer W, and is 270 to 280 mm (in the present preferred embodiment, 270 mm) when the diameter of the semiconductor wafer W is 300 mm. Each of the substrate support pins 77 is made of quartz. The substrate support pins 77 may be provided by welding on the upper surface of the holding plate 75 or machined integrally with the holding plate 75.

Referring again to FIG. 2, the four coupling portions 72 provided upright on the base ring 71 and the peripheral portion of the holding plate 75 of the susceptor 74 are rigidly secured to each other by welding. In other words, the susceptor 74 and the base ring 71 are fixedly coupled to each other with the coupling portions 72. The base ring 71 of such a holder 7 is supported by the wall surface of the chamber 6, whereby the holder 7 is mounted to the chamber 6. With the holder 7 mounted to the chamber 6, the holding plate 75 of the susceptor 74 assumes a horizontal attitude (an attitude such that the normal to the holding plate 75 coincides with a vertical direction). In other words, the holding surface 75a of the holding plate 75 becomes a horizontal surface.

A semiconductor wafer W transported into the chamber 6 is placed and held in a horizontal attitude on the susceptor 74 of the holder 7 mounted to the chamber 6. At this time, the semiconductor wafer W is supported by the 12 substrate support pins 77 provided upright on the holding plate 75, and is held by the susceptor 74. More strictly speaking, the 12 substrate support pins 77 have respective upper end portions coming in contact with the lower surface of the semiconductor wafer W to support the semiconductor wafer W. The semiconductor wafer W is supported in a horizontal attitude by the 12 substrate support pins 77 because the 12 substrate support pins 77 have a uniform height (distance from the upper ends of the substrate support pins 77 to the holding surface 75a of the holding plate 75).

The semiconductor wafer W supported by the substrate support pins 77 is spaced a predetermined distance apart from the holding surface 75a of the holding plate 75. The thickness of the guide ring 76 is greater than the height of the substrate support pins 77. Thus, the guide ring 76 prevents the horizontal misregistration of the semiconductor wafer W supported by the substrate support pins 77.

As shown in FIGS. 2 and 3, an opening 78 is provided in the holding plate 75 of the susceptor 74 so as to extend vertically through the holding plate 75 of the susceptor 74. The opening 78 is provided for the lower radiation thermometer 20 to receive radiation (infrared light) emitted from the lower surface of the semiconductor wafer W. Specifically, the lower radiation thermometer 20 receives the radiation emitted from the lower surface of the semiconductor wafer W through the opening 78 and the transparent window 21 mounted to the through hole 61b in the chamber side portion 61 to measure the temperature of the semiconductor wafer W. Further, the holding plate 75 of the susceptor 74 further includes four through holes 79 bored therein and designed so that lift pins 12 of the transfer mechanism 10 to be described later pass through the through holes 79, respectively, to transfer a semiconductor wafer W.

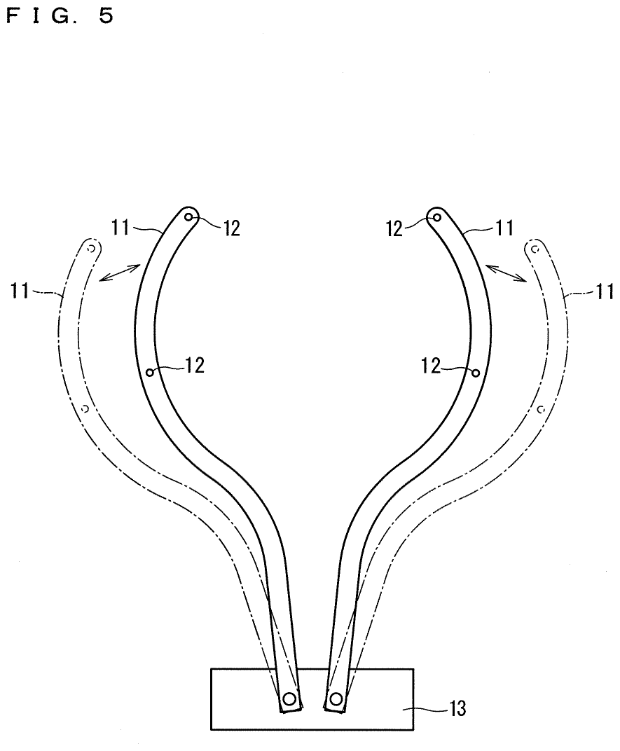

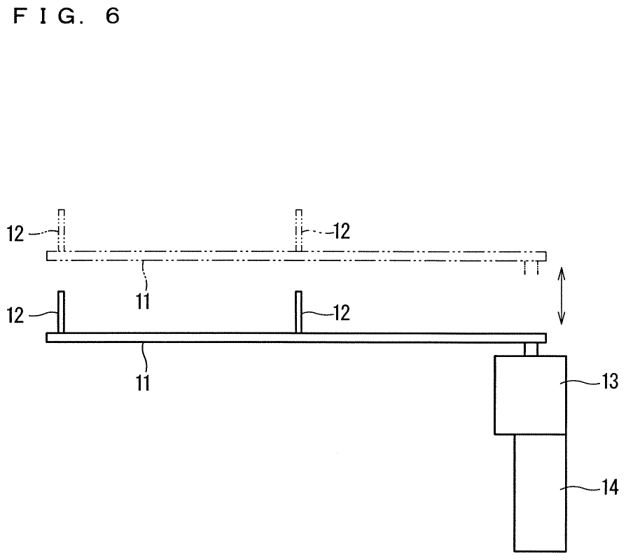

FIG. 5 is a plan view of the transfer mechanism 10. FIG. 6 is a side view of the transfer mechanism 10. The transfer mechanism 10 includes the two transfer arms 11. The transfer arms 11 are of an arcuate configuration extending substantially along the annular recessed portion 62. Each of the transfer arms 11 includes the two lift pins 12 mounted upright thereon. The transfer arms 11 and the lift pins 12 are made of quartz. The transfer arms 11 are pivotable by a horizontal movement mechanism 13. The horizontal movement mechanism 13 moves the pair of transfer arms 11 horizontally between a transfer operation position (a position indicated by solid lines in FIG. 5) in which a semiconductor wafer W is transferred to and from the holder 7 and a retracted position (a position indicated by dash-double-dot lines in FIG. 5) in which the transfer arms 11 do not overlap the semiconductor wafer W held by the holder 7 as seen in plan view. The horizontal movement mechanism 13 may be of the type which causes individual motors to pivot the transfer arms 11 respectively or of the type which uses a linkage mechanism to cause a single motor to pivot the pair of transfer arms 11 in cooperative relation.

The transfer arms 11 are moved upwardly and downwardly together with the horizontal movement mechanism 13 by an elevating mechanism 14. As the elevating mechanism 14 moves up the pair of transfer arms 11 in their transfer operation position, the four lift pins 12 in total pass through the respective four through holes 79 (with reference to FIGS. 2 and 3) bored in the susceptor 74, so that the upper ends of the lift pins 12 protrude from the upper surface of the susceptor 74. On the other hand, as the elevating mechanism 14 moves down the pair of transfer arms 11 in their transfer operation position to take the lift pins 12 out of the respective through holes 79 and the horizontal movement mechanism 13 moves the pair of transfer arms 11 so as to open the transfer arms 11, the transfer arms 11 move to their retracted position. The retracted position of the pair of transfer arms 11 is immediately over the base ring 71 of the holder 7. The retracted position of the transfer arms 11 is inside the recessed portion 62 because the base ring 71 is placed on the bottom surface of the recessed portion 62. An exhaust mechanism not shown is also provided near the location where the drivers (the horizontal movement mechanism 13 and the elevating mechanism 14) of the transfer mechanism 10 are provided, and is configured to exhaust an atmosphere around the drivers of the transfer mechanism 10 to the outside of the chamber 6.

Referring again to FIG. 1, the flash heating part 5 provided over the chamber 6 includes an enclosure 51, a light source provided inside the enclosure 51 and including the multiple (in the present preferred embodiment, 30) xenon flash lamps FL, and a reflector 52 provided inside the enclosure 51 so as to cover the light source from above. The flash heating part 5 further includes a lamp light radiation window 53 mounted to the bottom of the enclosure 51. The lamp light radiation window 53 forming the floor of the flash heating part 5 is a plate-like lamp cover window made of quartz. The flash heating part 5 is provided over the chamber 6, whereby the lamp light radiation window 53 is opposed to the upper chamber window 63. The flash lamps FL direct flashes of light from over the chamber 6 through the lamp light radiation window 53 and the upper chamber window 63 toward the heat treatment space 65.

The flash lamps FL, each of which is a rod-shaped lamp having an elongated cylindrical shape, are arranged in a plane so that the longitudinal directions of the respective flash lamps FL are in parallel with each other along a main surface of a semiconductor wafer W held by the holder 7 (that is, in a horizontal direction). Thus, a plane defined by the arrangement of the flash lamps FL is also a horizontal plane. A region in which the flash lamps FL are arranged has a size, as seen in plan view, greater than that of the semiconductor wafer W.

Each of the xenon flash lamps FL includes a cylindrical glass tube (discharge tube) containing xenon gas sealed therein and having positive and negative electrodes provided on opposite ends thereof and connected to a capacitor, and a trigger electrode attached to the outer peripheral surface of the glass tube. Because the xenon gas is electrically insulative, no current flows in the glass tube in a normal state even if electrical charge is stored in the capacitor. However, if a high voltage is applied to the trigger electrode to produce an electrical breakdown, electricity stored in the capacitor flows momentarily in the glass tube, and xenon atoms or molecules are excited at this time to cause light emission. Such a xenon flash lamp FL has the property of being capable of emitting extremely intense light as compared with a light source that stays lit continuously such as a halogen lamp HL because the electrostatic energy previously stored in the capacitor is converted into an ultrashort light pulse ranging from 0.1 to 100 milliseconds. Thus, the flash lamps FL are pulsed light emitting lamps which emit light instantaneously for an extremely short time period of less than one second. The light emission time of the flash lamps FL is adjustable by the coil constant of a lamp light source which supplies power to the flash lamps FL.

The reflector 52 is provided over the plurality of flash lamps FL so as to cover all of the flash lamps FL. A fundamental function of the reflector 52 is to reflect flashes of light emitted from the plurality of flash lamps FL toward the heat treatment space 65. The reflector 52 is a plate made of an aluminum alloy. A surface of the reflector 52 (a surface which faces the flash lamps FL) is roughened by abrasive blasting.

The halogen heating part 4 provided under the chamber 6 includes an enclosure 41 incorporating the multiple (in the present preferred embodiment, 40) halogen lamps HL. The halogen heating part 4 is a light irradiator that directs light from under the chamber 6 through the lower chamber window 64 toward the heat treatment space 65 to heat the semiconductor wafer W by means of the halogen lamps HL.

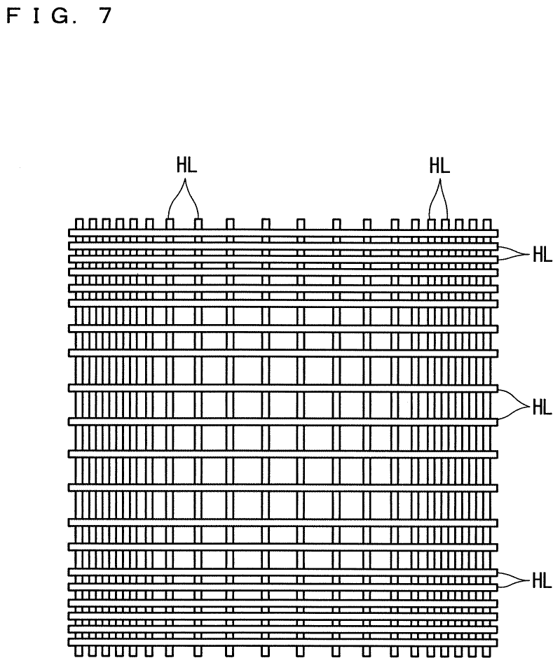

FIG. 7 is a plan view showing an arrangement of the multiple halogen lamps HL. The 40 halogen lamps HL are arranged in two tiers, i.e. upper and lower tiers. That is, 20 halogen lamps HL are arranged in the upper tier closer to the holder 7, and 20 halogen lamps HL are arranged in the lower tier farther from the holder 7 than the upper tier. Each of the halogen lamps HL is a rod-shaped lamp having an elongated cylindrical shape. The 20 halogen lamps HL in each of the upper and lower tiers are arranged so that the longitudinal directions thereof are in parallel with each other along a main surface of a semiconductor wafer W held by the holder 7 (that is, in a horizontal direction). Thus, a plane defined by the arrangement of the halogen lamps HL in each of the upper and lower tiers is also a horizontal plane.

As shown in FIG. 7, the halogen lamps HL in each of the upper and lower tiers are disposed at a higher density in a region opposed to a peripheral portion of the semiconductor wafer W held by the holder 7 than in a region opposed to a central portion thereof. In other words, the halogen lamps HL in each of the upper and lower tiers are arranged at shorter intervals in a peripheral portion of the lamp arrangement than in a central portion thereof. This allows a greater amount of light to impinge upon the peripheral portion of the semiconductor wafer W where a temperature decrease is prone to occur when the semiconductor wafer W is heated by the irradiation thereof with light from the halogen heating part 4.

The group of halogen lamps HL in the upper tier and the group of halogen lamps HL in the lower tier are arranged to intersect each other in a lattice pattern. In other words, the 40 halogen lamps HL in total are disposed so that the longitudinal direction of the 20 halogen lamps HL arranged in the upper tier and the longitudinal direction of the 20 halogen lamps HL arranged in the lower tier are orthogonal to each other.

Each of the halogen lamps HL is a filament-type light source which passes current through a filament disposed in a glass tube to make the filament incandescent, thereby emitting light. A gas prepared by introducing a halogen element (iodine, bromine and the like) in trace amounts into an inert gas such as nitrogen, argon and the like is sealed in the glass tube. The introduction of the halogen element allows the temperature of the filament to be set at a high temperature while suppressing a break in the filament. Thus, the halogen lamps HL have the properties of having a longer life than typical incandescent lamps and being capable of continuously emitting intense light. That is, the halogen lamps HL are continuous lighting lamps that emit light continuously for not less than one second. In addition, the halogen lamps HL, which are rod-shaped lamps, have a long life. The arrangement of the halogen lamps HL in a horizontal direction provides good efficiency of radiation toward the semiconductor wafer W provided over the halogen lamps HL.

A reflector 43 is provided also inside the enclosure 41 of the halogen heating part 4 under the halogen lamps HL arranged in two tiers (FIG. 1). The reflector 43 reflects the light emitted from the halogen lamps HL toward the heat treatment space 65.

As shown in FIG. 1, the heat treatment apparatus 1 includes the upper radiation thermometer 25 and the lower radiation thermometer 20. The upper radiation thermometer 25 is provided obliquely above the semiconductor wafer W held by the susceptor 74, and receives the infrared radiation emitted from the upper surface of the semiconductor wafer W to measure the temperature of the upper surface of the semiconductor wafer W. The infrared sensor 29 of the upper radiation thermometer 25 includes an optical element made of InSb (indium antimonide) so as to be able to respond to rapid changes in temperature of the upper surface of the semiconductor wafer W at the moment of flash irradiation. On the other hand, the lower radiation thermometer 20 is provided obliquely below the semiconductor wafer W held by the susceptor 74, and receives the infrared radiation emitted from the lower surface of the semiconductor wafer W to measure the temperature of the lower surface of the semiconductor wafer W.

The controller 3 controls the aforementioned various operating mechanisms provided in the heat treatment apparatus 1. The controller 3 is similar in hardware configuration to a typical computer. Specifically, the controller 3 includes a CPU that is a circuit for performing various computation processes, a ROM or read-only memory for storing a basic program therein, a RAM or readable/writable memory for storing various pieces of information therein, and a storage part (e.g., a magnetic disk or an SSD) for storing control software, data and the like thereon. The CPU in the controller 3 executes a predetermined processing program, whereby the processes in the heat treatment apparatus 1 proceed.

In the present preferred embodiment, the upper chamber window 63 which is a quartz window covering the top opening of the chamber 6 has an anti-reflective film formed thereon. The upper chamber window 63 is one of the quartz parts provided between the semiconductor wafer W held by the holder 7 and the flash lamps FL.

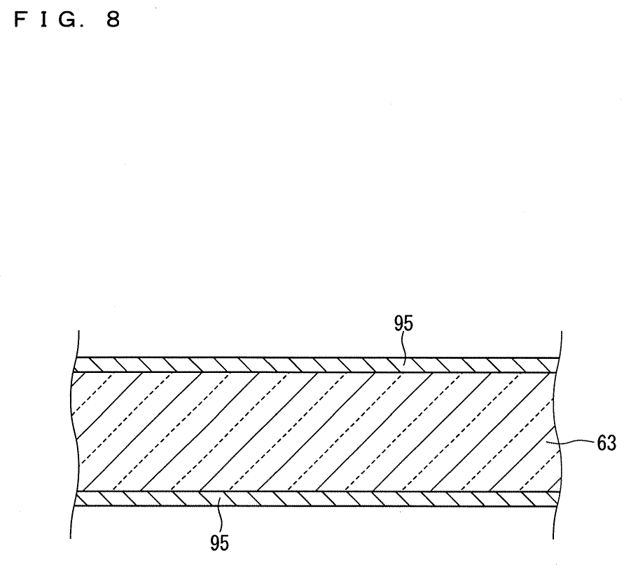

FIG. 8 is a partial sectional view of the upper chamber window 63 with an anti-reflective film 95 formed thereon. The anti-reflective film 95 is an optical thin film referred to also as an AR coating (Anti Reflection Coating). Specifically, the anti-reflective film 95 is a dielectric film made of a dielectric material which absorbs an extremely small amount of light (e.g., magnesium fluoride (MgF₂), titanium oxide (TiO₂), tantalum oxide (Ta₂O₅), and the like). The anti-reflective film 95 formed on the upper chamber window 63 is composed of a multi-layer combination of multiple types of dielectric films.

As shown in FIG. 8, the anti-reflective film 95 is formed on both an upper surface (a surface which faces the flash lamps FL) and a lower surface (a surface in contact with the heat treatment space 65 in the chamber 6) of the upper chamber window 63 in the present preferred embodiment. In addition, the anti-reflective film 95 is formed on the entire upper and lower surfaces of the upper chamber window 63. The thickness of the anti-reflective film 95 to be formed may have an appropriate value, but is, for example, less than 1 μm.

The upper chamber window 63 is a quartz window for transmitting flashes of light emitted from the flash lamps FL therethrough into the chamber 6. Thus, the flashes of light emitted from the flash lamps FL are reflected by the upper chamber window 63, and the anti-reflective film 95 formed on the upper chamber window 63 prevents the reflection of the flashes of light. Specifically, the anti-reflective film 95 formed on the upper chamber window 63 reduces the reflectance of light in a wavelength range corresponding to an emission spectrum of the flash lamps FL. More specifically, the anti-reflective film 95 formed on the upper chamber window 63 reduces the reflectance of light in a wavelength range including a wavelength such that an intensity relative to a maximum peak is not less than 0.1 in the emission spectrum of the flash lamps FL.

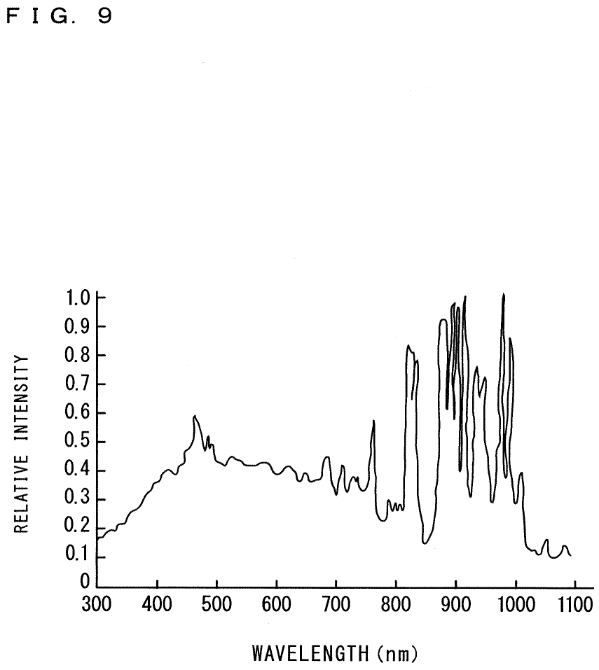

FIG. 9 is a graph showing part of the emission spectrum of the xenon flash lamps FL. The spectrum of the flash lamps FL is similar to that of sunlight, and the flash lamps FL emit radiation of an adequate intensity from short-wavelength ultraviolet to visible light regions. The flash lamps FL also emit strong radiation peculiar to xenon gas even in infrared regions. A target wavelength is a wavelength component such that the relative intensity is not less than 0.1 when the intensity of the maximum peak which has the highest intensity is 1 in the spectrum of the flash lamps FL as shown in FIG. 9. The target wavelength of the xenon flash lamps FL is between approximately 250 and 1200 nm. The anti-reflective film 95 formed on the upper chamber window 63 reduces the reflectance of light in a wavelength range including at least the aforementioned target wavelength. This restrains the upper chamber window 63 from reflecting the flashes of light emitted from the flash lamps FL.

The heat treatment apparatus 1 further includes, in addition to the aforementioned components, various cooling structures to prevent an excessive temperature rise in the halogen heating part 4, the flash heating part 5, and the chamber 6 because of the heat energy generated from the halogen lamps HL and the flash lamps FL during the heat treatment of a semiconductor wafer W. As an example, a water cooling tube (not shown) is provided in the walls of the chamber 6. Also, the halogen heating part 4 and the flash heating part 5 have an air cooling structure for forming a gas flow therein to exhaust heat. Air is supplied to a gap between the upper chamber window 63 and the lamp light radiation window 53 to cool down the flash heating part 5 and the upper chamber window 63.

Next, a treatment operation in the heat treatment apparatus 1 will be described. A typical heat treatment operation for an ordinary semiconductor wafer (product wafer) W that becomes a product will be described. A procedure for the treatment of the semiconductor wafer W which will be described below proceeds under the control of the controller 3 over the operating mechanisms of the heat treatment apparatus 1.

First, the valve 84 for supply of gas is opened, and the valves 89 and 192 for exhaust of gas are opened, so that the supply and exhaust of gas into and out of the chamber 6 start. When the valve 84 is opened, nitrogen gas is supplied through the gas supply opening 81 into the heat treatment space 65. When the valve 89 is opened, the gas within the chamber 6 is exhausted through the gas exhaust opening 86. This causes the nitrogen gas supplied from an upper portion of the heat treatment space 65 in the chamber 6 to flow downwardly and then to be exhausted from a lower portion of the heat treatment space 65.

The gas within the chamber 6 is exhausted also through the transport opening 66 by opening the valve 192. Further, the exhaust mechanism not shown exhausts an atmosphere near the drivers of the transfer mechanism 10. It should be noted that the nitrogen gas is continuously supplied into the heat treatment space 65 during the heat treatment of a semiconductor wafer W in the heat treatment apparatus 1. The amount of nitrogen gas supplied into the heat treatment space 65 is changed as appropriate in accordance with process steps.

Subsequently, the gate valve 185 is opened to open the transport opening 66. A transport robot outside the heat treatment apparatus 1 transports the semiconductor wafer W to be treated through the transport opening 66 into the heat treatment space 65 of the chamber 6. At this time, there is a danger that an atmosphere outside the heat treatment apparatus 1 is carried into the heat treatment space 65 as the semiconductor wafer W is transported into the heat treatment space 65. However, the nitrogen gas is continuously supplied into the chamber 6. Thus, the nitrogen gas flows outwardly through the transport opening 66 to minimize the outside atmosphere carried into the heat treatment space 65.

The semiconductor wafer W transported into the heat treatment space 65 by the transport robot is moved forward to a position lying immediately over the holder 7 and is stopped thereat. Then, the pair of transfer arms 11 of the transfer mechanism 10 is moved horizontally from the retracted position to the transfer operation position and is then moved upwardly, whereby the lift pins 12 pass through the through holes 79 and protrude from the upper surface of the holding plate 75 of the susceptor 74 to receive the semiconductor wafer W. At this time, the lift pins 12 move upwardly to above the upper ends of the substrate support pins 77.

After the semiconductor wafer W is placed on the lift pins 12, the transport robot moves out of the heat treatment space 65, and the gate valve 185 closes the transport opening 66. Then, the pair of transfer arms 11 moves downwardly to transfer the semiconductor wafer W from the transfer mechanism 10 to the susceptor 74 of the holder 7, so that the semiconductor wafer W is held in a horizontal attitude from below. The semiconductor wafer W is supported by the substrate support pins 77 provided upright on the holding plate 75, and is held by the susceptor 74. The semiconductor wafer W is held by the holder 7 in such an attitude that the front surface thereof that is patterned is the upper surface. A predetermined distance is defined between a back surface (a main surface opposite from the front surface) of the semiconductor wafer W supported by the substrate support pins 77 and the holding surface 75a of the holding plate 75. The pair of transfer arms 11 moved downwardly below the susceptor 74 is moved back to the retracted position, i.e. to the inside of the recessed portion 62, by the horizontal movement mechanism 13.

After the semiconductor wafer W is held from below in a horizontal attitude by the susceptor 74 of the holder 7 made of quartz, the 40 halogen lamps HL in the halogen heating part 4 turn on simultaneously to start preheating (or assist-heating). Halogen light emitted from the halogen lamps HL is transmitted through the lower chamber window 64 and the susceptor 74 both made of quartz, and impinges upon the lower surface of the semiconductor wafer W. By receiving light irradiation from the halogen lamps HL, the semiconductor wafer W is preheated, so that the temperature of the semiconductor wafer W increases. It should be noted that the transfer arms 11 of the transfer mechanism 10, which are retracted to the inside of the recessed portion 62, do not become an obstacle to the heating using the halogen lamps HL.

The temperature of the semiconductor wafer W is measured by the lower radiation thermometer 20 when the halogen lamps HL perform the preheating. Specifically, the lower radiation thermometer 20 receives infrared radiation emitted from the lower surface of the semiconductor wafer W held by the susceptor 74 through the opening 78 and passing through the transparent window 21 to measure the temperature of the semiconductor wafer W which is on the increase. The measured temperature of the semiconductor wafer W is transmitted to the controller 3. The controller 3 controls the output from the halogen lamps HL while monitoring whether the temperature of the semiconductor wafer W which is on the increase by the irradiation with light from the halogen lamps HL reaches a predetermined preheating temperature T1 or not. In other words, the controller 3 effects feedback control of the output from the halogen lamps HL so that the temperature of the semiconductor wafer W is equal to the preheating temperature T1, based on the value measured by the lower radiation thermometer 20. In this manner, the lower radiation thermometer 20 is a radiation thermometer for controlling the temperature of the semiconductor wafer W during the preheating.

After the temperature of the semiconductor wafer W reaches the preheating temperature T1, the controller 3 maintains the temperature of the semiconductor wafer W at the preheating temperature T1 for a short time. Specifically, when the temperature of the semiconductor wafer W measured by the lower radiation thermometer 20 reaches the preheating temperature T1, the controller 3 adjusts the output from the halogen lamps HL to maintain the temperature of the semiconductor wafer W at approximately the preheating temperature T1.

The flash lamps FL in the flash heating part 5 irradiate the front surface of the semiconductor wafer W held by the susceptor 74 with a flash of light when a predetermined time period has elapsed since the temperature of the semiconductor wafer W reached the preheating temperature T1. The flash of light emitted from the flash lamps FL is transmitted through the upper chamber window 63, and reaches the front surface of the semiconductor wafer W.

If the anti-reflective film 95 is not formed on the upper chamber window 63 as in the conventional manner, reflection occurs at an interface between air and the upper chamber window 63 made of quartz due to a difference in refractive index therebetween. Approximately 4% reflection occurs at the interface of the upper chamber window 63 because the refractive index of air is approximately 1 and the refractive index of quartz glass is approximately 1.5. In total, approximately 8% of the flash of light emitted from the flash lamps FL is lost when the flash of light is transmitted through the upper chamber window 63 because approximately 4% reflection occurs at each of the upper and lower surfaces of the upper chamber window 63.

In the present preferred embodiment, the anti-reflective film 95 is formed on the upper and lower surfaces of the upper chamber window 63. The anti-reflective film 95 reduces the reflectance of light in a wavelength range including at least a target wavelength when the target wavelength is a wavelength component such that the intensity relative to the maximum peak which has the highest intensity is not less than 0.1 in the spectrum of the flash lamps FL.

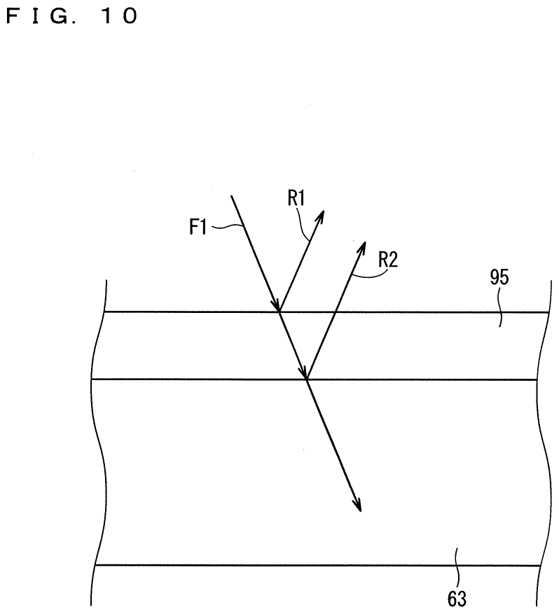

FIG. 10 is a schematic view for illustrating the principle of reflectance reduction using the anti-reflective film 95. Part of a flash of light F1 emitted from a flash lamp FL is reflected at an upper surface of the anti-reflective film 95 formed on the upper surface of the upper chamber window 63 (reflected light R1). Also, part of the flash of light F1 entering the anti-reflective film 95 is reflected at an interface between the upper chamber window 63 and the anti-reflective film 95 (reflected light R2). Refraction occurs in reality when the flash of light F1 enters the anti-reflective film 95 and the upper chamber window 63, but is not shown in FIG. 10.

The reflected light R1 at the upper surface of the anti-reflective film 95 and the reflected light R2 at the interface between the upper chamber window 63 and the anti-reflective film 95 are out of phase with each other by one-half wavelength, which in turn causes the peaks and valleys of both waveforms thereof to cancel each other, thereby weakening each other (optical interference phenomenon). Thus, the anti-reflective film 95 formed on the upper surface of the upper chamber window 63 is capable of weakening the reflected light from the upper surface thereof, i.e., capable of reducing the reflectance of the flash of light at the upper surface thereof. In other words, the anti-reflective film 95 having a structure in which the reflected light R1 and the reflected light R2 mutually weaken each other at the aforementioned target wavelength of the flash lamps FL is selected and formed on the upper chamber window 63. Similarly, the anti-reflective film 95 formed on the lower surface of the upper chamber window 63 is capable of reducing the reflectance of the flash of light at the lower surface thereof.

The flash of light emitted from the flash lamps FL is an intense flash of light emitted for an extremely short period of time ranging from about 0.1 to about 100 milliseconds as a result of the conversion of the electrostatic energy previously stored in the capacitor into such an ultrashort light pulse. Such an extremely short and intense flash of light enters the chamber 6 while being hardly reflected at the upper and lower surfaces of the upper chamber window 63, and impinges upon the front surface of the semiconductor wafer W. This causes the front surface temperature of the semiconductor wafer W to momentarily increase to a treatment temperature T2 and to thereafter decrease rapidly.

After a predetermined time period has elapsed since the completion of the flash heating using the flash irradiation, the halogen lamps HL turn off. This causes the temperature of the semiconductor wafer W to decrease rapidly from the preheating temperature T1. The lower radiation thermometer 20 measures the temperature of the semiconductor wafer W which is on the decrease. The result of measurement is transmitted to the controller 3. The controller 3 monitors whether the temperature of the semiconductor wafer W is decreased to a predetermined temperature or not, based on the result of measurement by means of the lower radiation thermometer 20. After the temperature of the semiconductor wafer W is decreased to the predetermined temperature or below, the pair of transfer arms 11 of the transfer mechanism 10 is moved horizontally again from the retracted position to the transfer operation position and is then moved upwardly, so that the lift pins 12 protrude from the upper surface of the susceptor 74 to receive the heat-treated semiconductor wafer W from the susceptor 74. Subsequently, the transport opening 66 which has been closed is opened by the gate valve 185, and the transport robot outside the heat treatment apparatus 1 transports the semiconductor wafer W placed on the lift pins 12 out of the chamber 6. Thus, the heating treatment of the semiconductor wafer W is completed.

In the present preferred embodiment, the anti-reflective film 95 is formed on the upper and lower surfaces of the upper chamber window 63 which is one of the quartz parts provided between the semiconductor wafer W held by the holder 7 and the flash lamps FL. The anti-reflective film 95 composed of a multi-layer combination of multiple types of dielectric films reduces the reflectance of light in a wavelength range including at least a target wavelength when the target wavelength is a wavelength component such that the intensity relative to the maximum peak having the highest intensity is not less than 0.1 in the emission spectrum of the flash lamps FL. This suppresses the reflection of flashes of light at the upper and lower surfaces of the upper chamber window 63 made of quartz, so that the transmittance of the upper chamber window 63 in the aforementioned wavelength range is not less than 99%.

Suppressing the reflection of the flashes of light from the upper chamber window 63 increases a temperature by which the front surface temperature of the semiconductor wafer W is increased due to the contribution of the flash irradiation, i.e. a jump temperature (T2−T1) from the preheating temperature T1 to the treatment temperature T2 during the flash heating. The increase in jump temperature lowers the preheating temperature T1 to obtain the same treatment temperature T2, thereby achieving a low thermal history.

In addition, suppressing the reflection of the flashes of light from the upper chamber window 63 reduces the light energy lost due to the reflection. This achieves the heating treatment with low power consumption for the attainment of the same treatment temperature T2.

While the preferred embodiment according to the present invention has been described hereinabove, various modifications of the present invention in addition to those described above may be made without departing from the scope and spirit of the invention. For example, the anti-reflective film 95 is formed on both the upper and lower surfaces of the upper chamber window 63 in the aforementioned preferred embodiment, but may be formed on only one of the upper and lower surfaces of the upper chamber window 63. As an example, if there is apprehension about metal contamination from the anti-reflective film 95, it is preferable to form the anti-reflective film 95 only on the outer surface (upper surface) opposite the inner surface (lower surface) of the upper chamber window 63 which is in contact with the heat treatment space 65 in the chamber 6. This reliably prevents the semiconductor wafer W and the structures (the susceptor 74 and the like) within the chamber 6 from being contaminated. However, the effect of suppressing the reflection resulting from the reflectance reduction is greater when the anti-reflective film 95 is formed on both the upper and lower surfaces of the upper chamber window 63.

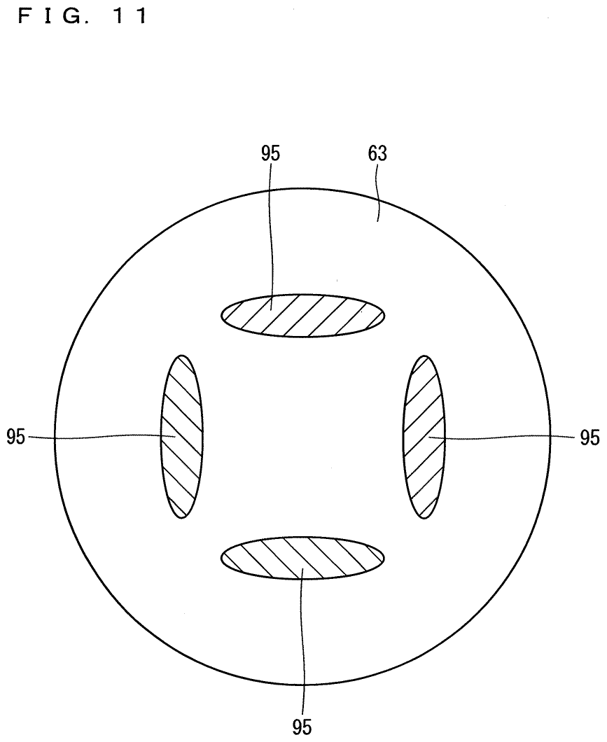

The anti-reflective film 95 is formed on the entire surfaces of the upper chamber window 63 in the aforementioned preferred embodiment, but may be formed on part of the upper chamber window 63. FIG. 11 is a view showing another example of the formation of the anti-reflective film 95. FIG. 11 is a plan view of the upper chamber window 63. In the example shown in FIG. 11, the anti-reflective film 95 is formed on locations of the upper chamber window 63 which are opposed to the peripheral portion of the semiconductor wafer W held by the holder 7. A temperature decrease is prone to occur in the peripheral portion of the semiconductor wafer W relative to the central portion thereof. The anti-reflective film 95 is formed on the locations of the upper chamber window 63 which are opposed to the peripheral portion to reduce the reflectance of the locations, thereby increasing the amount of light impinging upon the peripheral portion of the semiconductor wafer W. This increases the temperature of the peripheral portion of the semiconductor wafer W to improve the uniformity of an in-plane temperature distribution of the semiconductor wafer W.

The formation pattern of the anti-reflective film 95 formed on part of the upper chamber window 63 is not limited to the example of FIG. 11. It is sufficient to form the anti-reflective film 95 on a location of the upper chamber window 63 which is opposed to a region (cold spot) where temperature is lower relative to other regions in a temperature distribution occurring in the semiconductor wafer W when the semiconductor wafer W held by the holder 7 is irradiated with light from the halogen lamps HL and/or the flash lamps FL. This increases the amount of light impinging on the cold spot to relatively increase the temperature of the cold spot. As a result, the cold spot is eliminated, which in turn improves the uniformity of the in-plane temperature distribution of the semiconductor wafer W.

In the aforementioned preferred embodiment, the anti-reflective film 95 is formed on the upper chamber window 63 to reduce the reflectance of flashes of light from the flash lamps FL. The present invention, however, is not limited to this. An anti-reflective film may be used to reduce the reflectance of light from other heating light sources. Examples of the heating light sources other than the flash lamps FL include the halogen lamps HL, LEDs (Light Emitting Diodes), LDs (Laser Diodes), and VCSELs (Vertical Cavity Surface Emitting Lasers). The LEDs, the LDs, and the VCSELs are continuous lighting lamps that emit light continuously for not less than one second, and may be used as assist-heating light sources in the heat treatment apparatus 1 in place of the halogen lamps HL. Alternatively, the heating light sources may be discharge type arc lamps (e.g., xenon arc lamps).

An LED is a kind of diode, and emits light because of an electroluminescence effect when a forward voltage is applied thereto. An LD is an element which causes laser oscillation by passing an electric current through a semiconductor, and is also known as a semiconductor laser. The LD has high output conversion efficiency, and is capable of emitting light of high intensity as compared with the LED, as well as having a long life. A VCSEL is a kind of semiconductor laser, and emits light in a direction perpendicular to the surface of a semiconductor substrate. The VCSEL is capable of emitting light of high intensity as compared with the LED, and emits light of high directivity.

An anti-reflective film may be formed on a quartz part provided between the halogen lamps HL, the LEDs, the LDs or the VCSELs and the semiconductor wafer W held by the holder 7 to thereby suppress the reflection of light emitted from these heating light sources at the interface of the quartz part. It is, however, necessary to change the composition of the anti-reflective film in accordance with the spectrum of the heating light sources. Specifically, it is necessary to adjust the types of dielectric films constituting the anti-reflective film and the layer structure thereof so as to reduce light in a wavelength range corresponding to the spectrum of the heating light sources. It is preferable that the anti-reflective film reduces the reflectance of light in a wavelength range including a wavelength such that the intensity relative to the maximum peak is not less than 0.1 in the spectrum of the heating light sources.

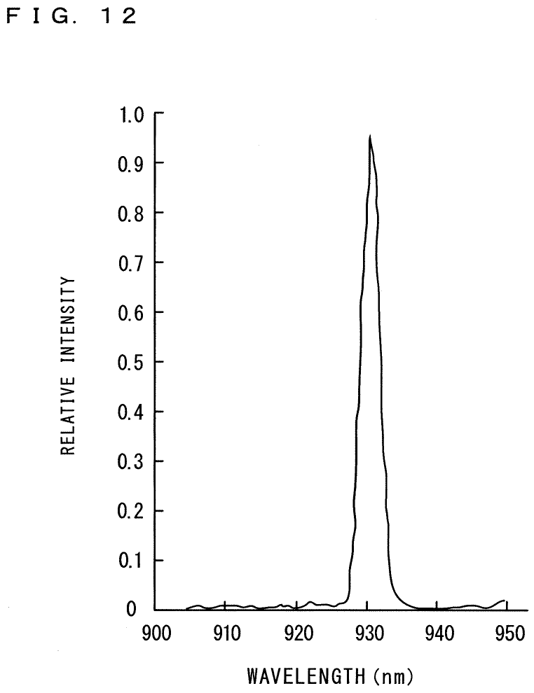

FIG. 12 is a graph showing the emission spectrum of the VCSEL. As compared with the spectrum of the flash lamps FL (FIG. 9), the spectrum of the VCSEL has a sharp peak in a very narrow wavelength range. In general, the narrower the wavelength range of a peak, the higher the reflection suppression effect achieved by an anti-reflective film having a simple structure. If the spectrum of the VCSEL is as shown in FIG. 12, even a single-layer anti-reflective film which reduces the reflectance of light in a wavelength range between 920 and 940 nm is capable of achieving a high reflection suppression effect, so that the transmittance of the quartz part is not less than 99.9%. On the other hand, since the spectrum of the halogen lamps HL is quite broad, it is necessary to form an anti-reflective film which reduces the reflectance of light in a wavelength range between approximately 400 and 4000 nm.

The quartz part on which the anti-reflective film is formed is not limited to the upper chamber window 63, but may be an appropriate quartz element depending on the heating light sources. For example, an anti-reflective film may be formed on the lamp light radiation window 53 which is the lamp cover window of the flash heating part 5 in place of or in addition to the upper chamber window 63 in the aforementioned preferred embodiment. If the heating light sources are provided under the chamber 6, such as the halogen lamps HL, it is sufficient to form an anti-reflective film on the lower chamber window 64 which is a quartz window covering the bottom opening of the chamber 6 and/or on the susceptor 74 of the holder 7. Alternatively, an anti-reflective film may be formed on lamp tube walls of the flash lamps FL and/or the halogen lamps HL. In short, it is sufficient to form an anti-reflective film on at least one quartz part present between the heating light sources and the semiconductor wafer W held by the holder 7.

Although the 30 flash lamps FL are provided in the flash heating part 5 according to the aforementioned preferred embodiment, the present invention is not limited to this. Any number of flash lamps FL may be provided. The flash lamps FL are not limited to the xenon flash lamps, but may be krypton flash lamps. Also, the number of halogen lamps HL provided in the halogen heating part 4 is not limited to 40. Any number of halogen lamps HL may be provided.

While the invention has been shown and described in detail, the foregoing description is in all aspects illustrative and not restrictive. It is therefore understood that numerous modifications and variations can be devised without departing from the scope of the invention.

What is claimed is:

1. A heat treatment apparatus for irradiating a substrate with light to heat the substrate, comprising:
a chamber for receiving a substrate therein;
a holder for holding said substrate in said chamber; and
a heating light source provided outside said chamber and for irradiating said substrate held by said holder with light,
wherein an anti-reflective film is formed on a quartz part provided between said heating light source and said substrate held by said holder.

2. The heat treatment apparatus according to claim 1,
wherein said anti-reflective film reduces the reflectance of light in a wavelength range corresponding to a spectrum of said heating light source.

3. The heat treatment apparatus according to claim 2,
wherein said anti-reflective film reduces the reflectance of light in a wavelength range including a wavelength such that an intensity relative to a maximum peak is not less than 0.1 in said spectrum of said heating light source.

4. The heat treatment apparatus according to claim 1,
wherein said quartz part is at least one part selected from the group consisting of a quartz window covering an opening of said chamber, a susceptor of said holder, a lamp cover window provided in said heating light source, and a lamp tube wall of said heating light source.

5. The heat treatment apparatus according to claim 4,
wherein said anti-reflective film is formed on both surfaces of said quartz part.

6. The heat treatment apparatus according to claim 4,
wherein said anti-reflective film is formed on one surface of said quartz part.

7. The heat treatment apparatus according to claim 6,
wherein said quartz part is said quartz window, and
wherein said anti-reflective film is formed on an outer surface opposite an inner surface of said quartz window which is in contact with a heat treatment space in said chamber.

8. The heat treatment apparatus according to claim 4,
wherein said quartz part is said quartz window, and
wherein said anti-reflective film is formed on a location opposed to a region where temperature is relatively low in a temperature distribution occurring in said substrate when said substrate held by said holder is irradiated with light.

9. The heat treatment apparatus according to claim 1,
wherein said anti-reflective film is a dielectric film.

10. The heat treatment apparatus according to claim 1,
wherein said heating light source is one selected from the group consisting of a flash lamp, a halogen lamp, a light emitting diode, a laser diode, and a vertical cavity surface emitting laser.
